(19) United States
(12) Patent Application Publication
(10) Pub. No.: US 2010/0193128 A1
(43) Pub. Date: Aug. 5, 2010

(54) SURFACE TREATMENT APPARATUS

(75) Inventors: Yuuki Koumura, Kawasaki-shi (JP); Yasushi Shinno, Kawasaki-shi (JP)

Correspondence Address: FITZPATRICK CELLA HARPER & SCINTO, 1290 Avenue of the Americas, NEW YORK, NY, 10104-3800, US

(73) Assignee: CANON ANELVA CORPORATION, Kawasaki-shi, Kanagawa-ken (JP)

(21) Appl. No.: 12/438,014

(22) PCT Filed: Jul. 4, 2008
(86) PCT No.: PCT/JP2008/062198

§ 371 Date: Apr. 21, 2010

(30) Foreign Application Priority Data
Jul. 4, 2007 (JP) 2007-176287

(51) Int. Cl. H01L 21/306; C23F 1/08; B05C 11/00; C23C 16/513

(52) U.S. Cl. 156/345.28; 156/345.48; 118/712; 118/723 I

(57) ABSTRACT

A surface treatment apparatus generates resonance on a line including an electrode. The surface treatment apparatus has a vacuum container (1) wherein a wafer (4) is stored and vacuum evacuation is made possible; and an upper electrode (3) and a lower electrode (5) arranged to face each other in the vacuum container (1). The surface treatment apparatus is provided with a high frequency power supply (16), which supplies the upper electrode (3) with high frequency power through a matching circuit (17); and a high frequency power supply (18), which supplies the lower electrode (5) with high frequency power through a matching circuit (19). Furthermore, the surface treatment apparatus is provided with a resonance adjusting section (resonance circuit) (60) connected between the lower electrode (5) and the ground; and a treatment gas supplying mechanism (not shown in the figure) for supplying the treatment gas into the vacuum container (1). The surface treatment apparatus is also provided with electrical length adjusting sections (50, 70), which are electrode phase position adjusting means for adjusting the phase positions of the electrodes (3, 5).

### TECHNICAL FIELD

The present invention relates to a surface treatment apparatus which performs surface treatment on a semiconductor substrate or the like.

### BACKGROUND ART

Conventionally, in a manufacturing process in a semiconductor apparatus or the like, a surface treatment apparatus using a plasma process such as etching, sputtering, plasma CVD, or ashing is used. A surface treatment apparatus of this type is configured to perform a predetermined process on the surface of a substrate to be processed or wafer by generating a plasma in a vacuum chamber.

A surface treatment apparatus using an RF plasma, in particular, starts electric discharge by applying RF waves to electrodes via matching circuits. In the conventional apparatus, the matching circuits match impedances to minimize reflected waves against incident powers from power supplies. This impedance matching is, however, viewed from the RF power supplies but is not viewed from a plasma as a load. For this reason, matching by the matching circuits cannot cause resonance in the transmission system including the electrodes. If, however, the RF circuits including the electrodes are set in a resonant state, it is possible to efficiently supply power to the electrodes. This can increase the plasma density or decrease the discharge start pressure.

A conventional technique will be described below by exemplifying a sputtering apparatus. Patent reference 1 discloses a capacitive coupling type sputtering apparatus of a so-called two-frequency scheme of applying RF powers having different frequencies to the upper and lower electrodes in the form of parallel plates. The circuit arrangement and operation of this apparatus will be described with reference to FIG. 8.

Referring to FIG. 8, reference numeral 1001 denotes a vacuum chamber; 1002, a target; 1003, an upper electrode; 1004, a wafer; 1005, a lower electrode; and 200, a magnet for magnetizing a plasma. A plasma is generated between the target 1002 and the wafer 1004. A 13.56-MHz RF power supply is connected to the upper electrode 1003 via a matching circuit. A 100-MHz RF power supply is connected to the lower electrode 1005 via a matching circuit. A resonant circuit 104b including C₅, L, and Cₛ is connected between the lower electrode 1005 and the matching circuit. A resonant frequency f₀ of a series resonant circuit including L and Cₛ of these components is equal to a frequency of 13.56 MHz applied to the target 1002.

That is,

[Mathematical 1]

f₀=1/└2π\sqrt{(LC_{S})}┘13.56 MHz

This can prevent a high frequency of 13.56 MHz from being applied to the lower electrode (susceptor) 1005 and perform bias sputtering on a thin insulating film without damaging a wafer.

Patent reference 1: Japanese Patent Laid-Open No. 63-50025

### DISCLOSURE OF INVENTION

### Problems that the Invention is to Solve

The above conventional technique however has the following problems.

In the above conventional apparatus, the resonant circuit is configured to ground the lower electrode. For this reason, no resonance occurs in the circuit including the electrodes. If resonance occurs in a wider range, the value of a current flowing in the circuit increases, resulting in an increase in the potential difference between the electrodes.

When such resonance occurs, a maximum current and a minimum voltage appear at a node of the resonance and a maximum voltage and a minimum current appear at an antinode of the same resonance depending on the electrode positions on a distribution constant circuit. The voltage/current ratio changes at an intermediate position. Consider actual apparatuses. The positions of the electrodes and the dielectric constant differences between dielectric substances in the respective apparatuses do not perfectly coincide with each other. That is, so-called apparatus differences occur. As a consequence, different plasma states appear in the respective apparatuses. In addition, as an apparatus is operated, a film adheres to a wall of a process chamber, resulting in a change in circuit state. As a consequence, the plasma state changes for each lot.

For example, in an inductively coupled plasma generator, when a current is supplied to the coil, a voltage is generated by the impedance of the coil. This causes capacitive coupling as well as inductive coupling, resulting in a decrease in inductive coupling efficiency and etching of an insulator, Si plate, or the like covering each electrode.

It is, therefore, an object of the present invention to provide a surface treatment apparatus which can cause resonance on a line including electrodes.

### Means of Solving the Problems

In order to achieve the above object, according to one aspect of the present invention, there is provided a surface treatment apparatus which comprises a vacuum chamber in which a substrate to be processed is accommodated and which is configured to be evacuated,

an upper electrode and a lower electrode which are arranged in the vacuum chamber so as to face each other,

first RF power supply means for supplying first RF power to the upper electrode via a first matching circuit,

second RF power supply means for supplying second RF power to the lower electrode via a second matching circuit,

a resonant circuit which is connected between the lower electrode and ground, and

process gas supply means for supplying a process gas into the vacuum chamber, and performs treatment on a surface of the substrate by generating a plasma of the process gas between the upper electrode and the lower electrode, the surface treatment apparatus comprising:

electrode phase position adjusting means for adjusting phase positions of the electrodes.

### EFFECTS OF THE INVENTION

According to the present invention, there can be provided a surface treatment apparatus which can cause resonance on a line including electrodes.

### BRIEF DESCRIPTION OF DRAWINGS

FIG. 1 is a view showing a surface treatment apparatus according to an embodiment of the present invention;

FIG. 2 is a simplified circuit diagram for explaining a resonant state;

FIG. 3 is a view for explaining the effective length of an electric line at an end portion;

FIG. 4 is a graph for explaining the effective length of an electric line in terms of impedance;

FIG. 5 is a view showing the flows of currents in an electrode portion;

FIG. 6 is a view showing the flows of currents in the electrode portion;

FIG. 7 is a view showing a maximum current mode and a maximum voltage mode in the electrode portion; and

FIG. 8 is a sectional view of a sputtering apparatus according to a conventional technique.

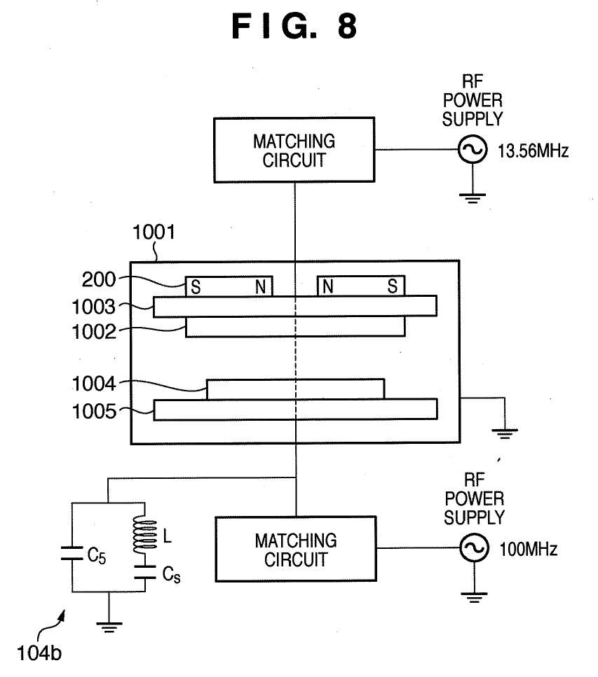

### BEST MODE FOR CARRYING OUT THE INVENTION

An embodiment of the film forming apparatus of the present invention will be described in detail below. The constituent elements described in this embodiment are merely exemplary. The technical range of the present invention is defined by claims, but is not limited by each embodiment to be described below.

The embodiment of the present invention will be described next with reference to the accompanying drawings.

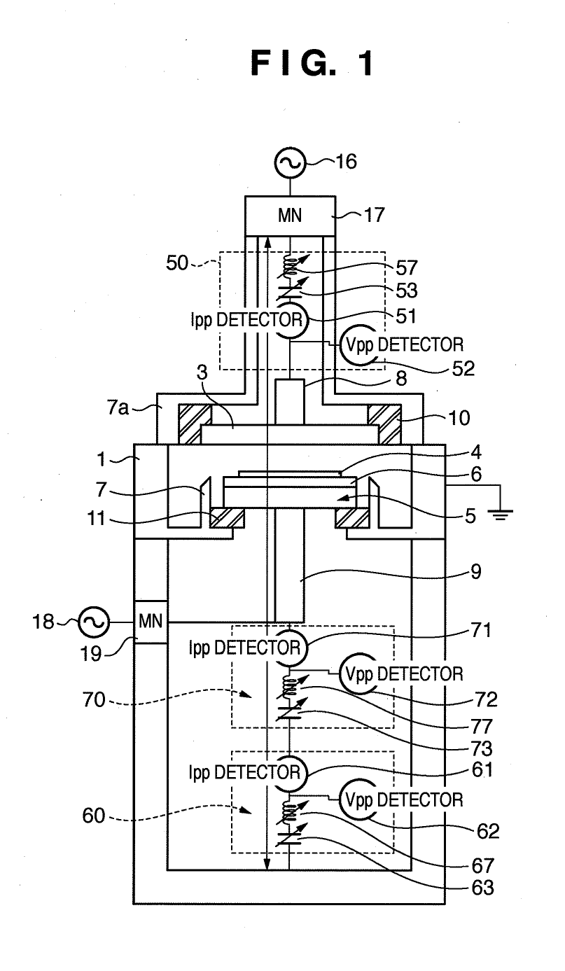

FIG. 1 is a view showing a surface treatment apparatus according to an embodiment of the present invention. The surface treatment apparatus according to the embodiment shown in FIG. 1 is an etching apparatus.

Referring to FIG. 1, reference numeral 1 denotes a vacuum chamber; 3, an upper electrode; 8, an upper electrode guide rod; 5, a lower electrode; 9, a lower electrode guide rod; 4, a wafer (substrate) to be processed which is accommodated in the vacuum chamber 1; 6, an electrostatic chuck for wafer chucking; 7, a lower electrode shield; 50, an electrical length adjusting unit including a capacitor, an inductor, and the like; 51, a p-p current detector; and 52, a p-p voltage detector. The upper electrode 3 and the lower electrode 5 are arranged in the vacuum chamber so as to face each other. The upper electrode 3 is insulated from an outer wall at ground potential by an insulating material 10. The lower electrode 5 is insulated from an outer wall at ground potential by an insulating material 11. The upper electrode 3 is connected to an RF power supply 16 (first RF power supply means) in the VHF band (preferably 60 MHz) via the first matching circuit in a matching device 17. The lower electrode 5 is connected to an RF power supply 18 (second RF power supply means) in the band between the MF band and the HF band (preferably 1.6 MHz) via the second matching circuit in a matching device 19. Although not shown, an evacuation mechanism and a process gas supply mechanism are arranged in the vacuum chamber 1, which also includes a substrate transfer mechanism.

When this etching apparatus is made to operate, the vacuum chamber 1 is evacuated to a predetermined pressure by using the evacuation mechanism, and a process gas is supplied from the lower surface of the upper electrode 3 into the vacuum chamber up to a predetermined pressure through the gas supply mechanism (not shown). Thereafter, the first RF power in the VHF band (preferably 60 MHz) and the second RF power in the band between the MF band and the HF band (preferably 1.6 MHz) are respectively applied to the upper electrode 3 and the lower electrode 5.

A plasma having a relatively high density and an etchant are generated by the RF power in the VHF band which is applied to the upper electrode 3. Ion impact energy is controlled by the RF power in the band between the MF band and the HF band which is applied to the lower electrode 5 independently of a plasma density, thereby executing a desired etching process. The following operation is performed to further increase this plasma density.

When injected power reaches 60% of that in steady operation and the plasma density becomes constant, a variable capacitor 63 is adjusted to achieve a resonance peak by using the current and voltage indicated by an Ipp detector (current measuring instrument) 61 and a Vpp detector (voltage measuring instrument) 62 for the lower electrode 5. This implements resonance in a space below the lower electrode 5. Implementing resonance in this manner will increase the plasma electronic density between the two electrodes. As a consequence, the dissociation of the process gas progresses, and the dissociated radial density increases. This makes it possible to obtain high selectivity, an etched shape without any bowing, and a uniform in-plane distribution.

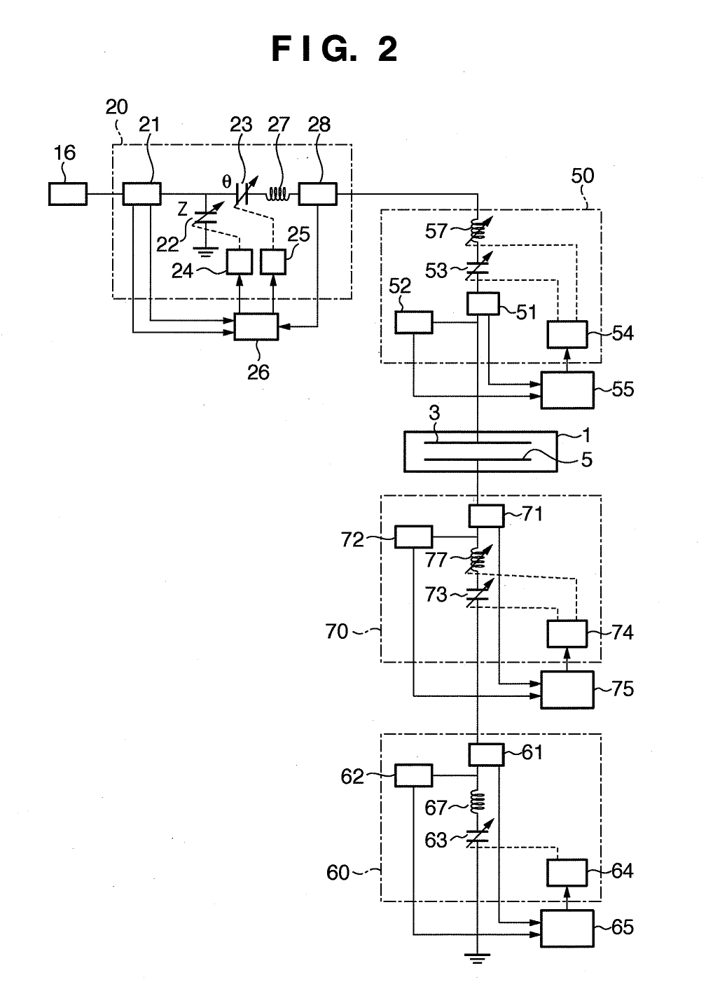

Matching adjustment and resonance adjustment which are substantial parts of this embodiment will be described next with reference to FIG. 2. FIG. 2 does not illustrate the RF power supply 18 and matching device 19 of the lower electrode 5. The RF power supply 16 is connected to the upper electrode 3 through the matching device 17. The matching device 17 includes an impedance measuring instrument 21 which measures a phase and an amplitude, a plasma generation measuring instrument 28 which detects the generation of a plasma, variable capacitors 22 and 23 constituting a matching circuit, and a coil 27. Motor units 24 and 25 respectively control the variable capacitors 22 and 23. A matching controller 26 receives signals from the plasma generation measuring instrument 28 and the impedance measuring instrument 21, and sends command signals to the motor units 24 and 25 to make the capacitors 22 and 23 take desired values.

The lower electrode 5 is connected to ground via an electrical length adjusting unit 70 and a resonance adjusting unit 60. The resonance adjusting unit 60 includes a variable inductor 67 and the variable capacitor 63, which constitute a resonant circuit, and a resonance controller 65 which sends a command signal to a motor unit 64 which drives the variable capacitor 63. The resonance adjusting unit 60 includes the p-p current detector 61 which detects the value of a peak-to-peak current and sends it to the resonance controller 65 and the p-p voltage detector 62 which detects the value of a peak-to-peak voltage and sends it to the resonance controller 65.

The matching device 17 and the resonance adjusting unit 60 operate in the following manner. When the RF power supply 16 supplies RF power between the two electrodes 3 and 5, a plasma is generated. Upon detecting the generation of a plasma, the plasma generation measuring instrument 28 sends a signal to the matching controller 26. The impedance measuring instrument 21 sends the detected current/voltage phase difference and the value of the impedance obtained from the measured voltage and current to the matching controller 26. The matching controller 26 sends signals to the motor units 25 and 24 so as to make the value of the impedance equal to the value of the RF power supply 16 and reduce the current/voltage phase difference to zero. The motor units 25 and 24 rotate in accordance with the values of these signals to adjust the values of the variable capacitors 23 and 22.

The resonance adjusting unit 60 starts controlling the resonant circuit at a timing near the timing when the power reaches 60% in a steady state. The p-p current detector 61 sends the detected peak-to-peak current value to the resonance controller 65. The p-p voltage detector 62 sends the detected peak-to-peak voltage value to the resonance controller 65. The resonance controller 65 determines the direction in which the capacitance value of the variable capacitor 63 changes and its value so as to maximize the value of voltage x current, and sends a signal to the motor unit 64. The motor unit 64 changes the variable capacitor 63 in accordance with the instruction. In this embodiment, the resonance adjusting unit 60 is not provided with any phase measuring instrument. If, however, the phase measuring instrument detects a current/voltage phase difference and sends the value to the resonance controller, it is easy to calculate in which direction the variable capacitor 63 should be changed to which extent. The resonance adjusting unit 60 therefore preferably includes a phase measuring instrument. It suffices to adjust the variable inductor 67 instead of the variable capacitor to cause resonance.

After resonance is implemented in this manner, the resonance positions of the electrodes are adjusted in the following sequence. In order to adjust the phase positions of the electrodes 5 and 3 in a resonant state, the phase positions of the upper and lower electrodes are changed by using the electrical length adjusting unit 50 provided above the upper electrode 3 and the electrical length adjusting unit 70 provided below the lower electrode. Note that the electrical length adjusting units 50 and 70 respectively form electrode phase position adjusting means. As the phase positions of the upper and lower electrodes change in this manner, the voltage/current ratios at the upper and lower electrode change. This can change the plasma into a desired state.

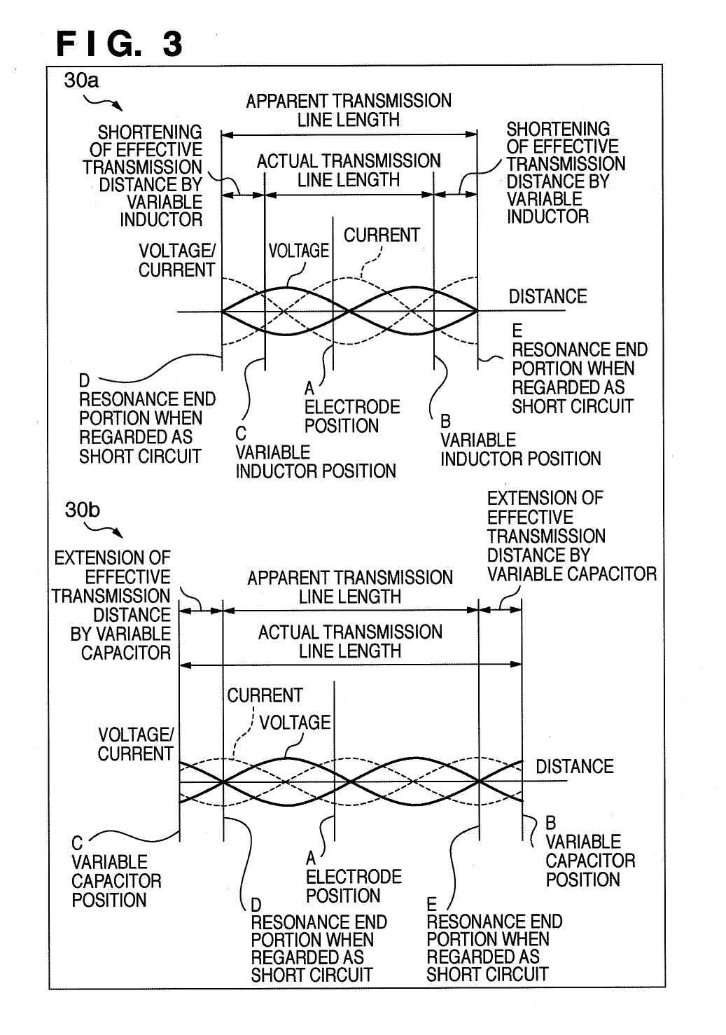

FIG. 3 is a view showing electrode phase position adjustment. A distribution constant circuit having one end short-circuited and an electrode located near the center does not properly resonate without having a length of an integer multiple of ½ wavelength. In addition, to make a current peak appear near the electrode, the electrode needs to be positioned near the center of one wavelength. A variable capacitor has the effect of shortening the short circuit end (increasing the effective length). Therefore, changing the size of the capacitor can change the effective length of the resonant circuit. Referring to 30b in FIG. 3, “the actual transmission line length” from a variable capacitor position B to a variable capacitor position C is longer than the resonant circuit length corresponding to one wavelength. In this case as well, properly changing the capacitor value can make the apparent resonant circuit length equal to “the apparent transmission line length” between resonance end portions E and D which is equal to one wavelength.

Furthermore, using such a variable capacitor can locate an electrode position A indicated by 30a in FIG. 3 at a current peak position by adjusting the balance between upper and lower capacitor values. Similar adjustment can be made by changing the inductor instead of the capacitor. Note that if one end of the resonant circuit is open and the other is short-circuited, resonance can be generated at half-wavelength.

In this embodiment, the lower electrode is provided with the resonance adjusting unit 60 and the electrical length adjusting unit 70. However, it suffices to omit one of them. If, for example, the electrical length adjusting unit 70 is omitted, the remaining resonance adjusting unit 60 serves both for resonance and for electrical length adjustment. This can simplify the apparatus and reduce the cost. In addition, since resonance adjustment and electrical length adjustment are performed in the same place, adjustment can be speeded up.

An idea on which the method of adjusting the effective line length of resonance and electrode positions is based will be described by using equations.

Let L be the inductance of the two lines per unit length, C be an electrostatic capacitance between the two lines per unit length, R be the go-and-return conductor resistance of the two lines per unit length, and S be the leakage conductance between the two lines per unit length. Letting E_{y} be the potential difference between the two lines and I_{y} be a current on the conductor at a point on the conductor which is located at a distance y measured from the left end power supply side, the following equations are obtained:

−dE_{y}/d_{y}=(R+jωL)·I_{y}=Z·I_{y}

−dI_{y}/d_{y}=(S+jωC)·E_{y}=Y·E_{y}

The following equations can be obtained by solving the above equations.

$$\begin{matrix}[ Mathematical 2 ] & \\ {E}_{y} = {K}_{1} sinh γ y + {K}_{2} cosh γ y \\ γ = \sqrt{YZ} \\ {I}_{y} = - ( 1 / {Z}_{ω} ) ( {K}_{1} cosh γ y + {K}_{2} sinh γ y ) & \end{matrix}$$

Letting Eₛ and Iₛ be the potential and current at the sending end, that is, y=0, equation (1) can be obtained:

$$\begin{matrix}[ Mathematical 3 ] & \\ [ \begin{matrix}{E}_{y} \\ {I}_{y}\end{matrix} ] \begin{matrix}= \\ =\end{matrix} [ \begin{matrix}cosh γ y & - {Z}_{ω } sinh γ y \\ - ( 1 / {Z}_{ω} ) sinh γ y & cosh γ y\end{matrix} ] [ \begin{matrix}{E}_{s} \\ {I}_{s}\end{matrix} ] & ( 1 )\end{matrix}$$

Letting Eᵣ and Iᵣ be the voltage and current at the receiving end, that is, y=1, equation (2) can be obtained:

$$\begin{matrix}[ Mathematical 4 ] & \\ [ \begin{matrix}{E}_{s} \\ {I}_{s}\end{matrix} ] \begin{matrix}= \\ =\end{matrix} [ \begin{matrix}cosh γ l & - {Z}_{ω } sinh γ l \\ - ( 1 / {Z}_{ω} ) sinh γ l & cosh γ l\end{matrix} ] [ \begin{matrix}{E}_{r} \\ {I}_{r}\end{matrix} ] & ( 2 )\end{matrix}$$

In a case of a receiving end short circuit, Eᵣ=0. The following equation can therefore be obtained from equation (2).

[Mathematical 5]

Iₛ=(cos βl/jZ_{ω}·sin βl)Eₛ

Note, however, that no loss is assumed, and R=0 and S=0.

[Mathematical 6]

Z_{ω}=\sqrt{Z/Y}=\sqrt{L/C},α=0,β=ω\sqrt{LC}

Substitution of these values into equation (2) yields equation (3) given below.

$$\begin{matrix}[ Mathematical 7 ] & \\ \{ \begin{matrix}{E}_{y} = ( sin β ( l - y ) / sin β l ) {E}_{s} \\ {I}_{y} = - j ( cos β ( l - y ) / {Z}_{ω} \cdot sin β l ) {E}_{s}\end{matrix} & ( 3 )\end{matrix}$$

When 1−y=x is used for equation (3) representing the impedance when a point y is viewed from the right, a sending-end impedance Zₓ takes the following pure reactance.

[Mathematical 8]

Z=jZ_{ω}tan βx=jZ_{ω}tan(2πx/λ)

According to this, this system becomes a series resonance system if it has a length represented by x=λ/2.

When this system is terminated at L, the sending-end impedance: Zₓ is obtained as follows on the basis of the relationship with Eᵣ=jωL·Iᵣ, assuming that the conductor has no loss and 1 is regarded as x.

$$\begin{matrix}[ Mathematical 9 ] & \\ \begin{matrix}{Z}_{x} = j {Z}_{ω} ( ω L cos β x + {Z}_{ω} sin β x ) / ( {Z}_{ω} cos β x - ω L sin β x ) \\ = j {Z}_{ω} tan ( β x + ϕ ) \\ = j {Z}_{ω} tan ( β ( x + {x}_{L} ) )\end{matrix} & \end{matrix}$$

In this case

[Mathematical 10]

φ=tan⁻¹ωL/Z_{w}X_{L}=φ/β (4)

This indicates that this system has the same characteristic as that of a short-circuited resonant line longer than the system by X_{L} and is equivalent to the operation of extending the short-circuited resonant line by X_{L}.

When this system is terminated at C, the sending-end impedance: Zₓ is obtained as follows on the basis of the relationship with Eᵣ=Iᵣ/jωC, assuming that the conductor has no loss and l is regarded as x.

$$\begin{matrix}[ Mathematical 11 ] & \\ \begin{matrix}{Z}_{x} = j {Z}_{ω} ( cos β x / ω C + {Z}_{ω} sin β x ) / ( {Z}_{ω} cos β x - sin β x / ω C ) \\ = j {Z}_{ω} tan ( β x - θ ) \\ = j {Z}_{ω} tan ( β ( x - {x}_{c} ) )\end{matrix} & \\ [ Mathematical 12 ] & \\ θ = {tan}^{- 1} 1 / {Z}_{ω} ω C \\ {X}_{c} = θ / β & ( 5 )\end{matrix}$$

This indicates that this system has the same characteristic as that of a short-circuited resonant line longer than the system by X_{L} and is equivalent to the operation of shortening the short-circuited resonant line by X_{L}.

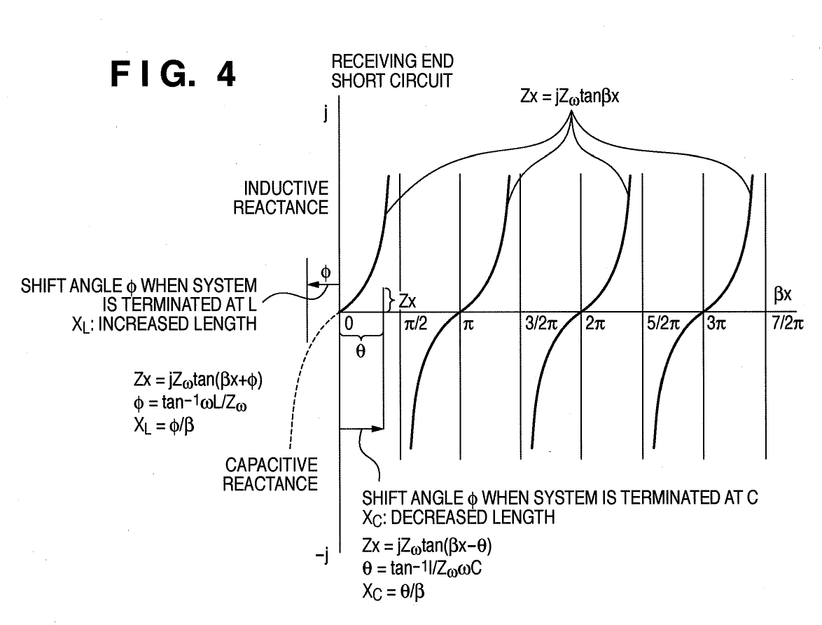

Changes in this line length are indicated by equations (4) and (5). FIG. 4 illustrates this change. A change in effective distance when this system is terminated at L or C is determined by the magnitude of the terminated capacitance or inductance, the characteristic impedance of the line, and the power supply frequency. For this reason, when, for example, a variable capacitor 73 on the lower electrode 5 side is changed, the effective line length changes, and the electrode phase position changes. However, since the line length changes, no resonance occurs. In order to maintain resonance by canceling this change in line length, it suffices to change a variable capacitor 53 on the upper electrode 3 side by the same amount in the opposite direction. In practice, however, since the characteristic impedance of the line differs depending on the place, it is necessary to change the capacitor so as to satisfy the equation in consideration of this. Although a criterion for such a change can be roughly calculated, a change in plasma state and the like cannot be calculated in practice. For this reason, when rough adjustment is performed on the basis of calculated values, in order to perform detailed adjustment, it is necessary to monitor a current/voltage state so as to satisfy resonance and set the electrode position in accordance with a desired current/voltage state while adjusting the circuit state accordingly.

Although actual adjustment is performed as follows, the adjustment is similar in many respects to the adjustment of the matching circuit and resonant circuit. Only an idea for such adjustment will be described. The phase distance difference between an Ipp detector 71 and a Vpp detector 72 and the phase distances to the upper and lower electrodes 3 and 5 are calculated in advance. In addition, the phase distances are checked in advance by measurement. The variable capacitor 73 or a variable inductor 77 is changed so as to set the ratio of Vpp (voltage) and Ipp (current) at the upper and lower electrodes 3 and 5 to a desired value in accordance with the values measured by the Ipp detector 71 and the Vpp detector 72. The variable capacitor 53 or variable inductor 77 on the upper electrode side is changed in accordance with this change, and the resonance adjusting unit 60 is also changed as needed.

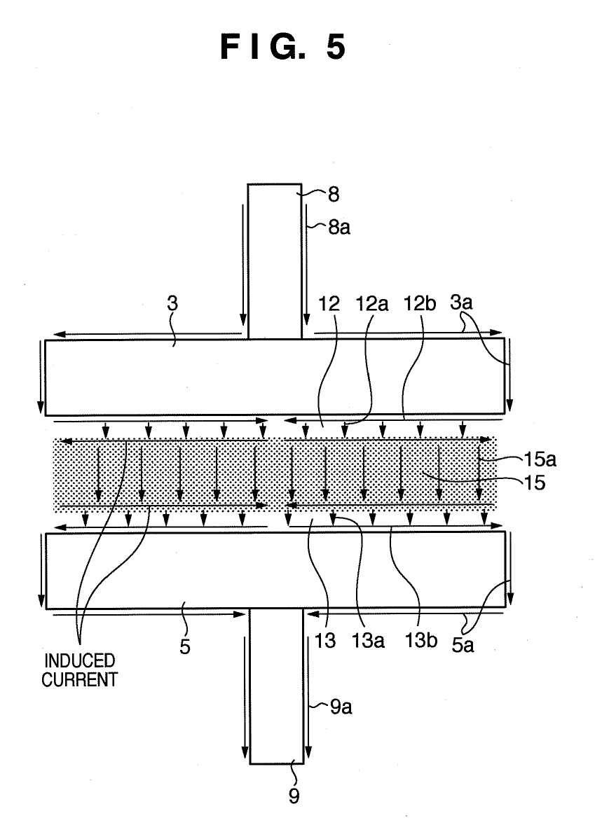

Points to be considered in terms of apparatus structure and the reason why it does not matter whether to provide a resonance adjusting unit or electrical length adjusting unit for a resonant circuit on the upper electrode 3 side or the lower electrode 5 side will be described next with reference to FIGS. 5, 6, and 1. Referring to these drawings, reference numeral 8 denotes the upper electrode conduction rod. An RF conduction current 8a flows on the surface of the upper electrode conduction rod 8. The conduction current 8a flows as an upper electrode outside current 3a on the surface of the upper electrode 3, and also flows as an upper electrode plasma side current 12b on the surface of the upper electrode 3. Electric charge stays on the electrode surface because this current has no place to go. An upper sheath current 12a indicating the sum of a displacement current, ion current, and electronic current flows in an upper sheath 12 in accordance with the electric field induced by this electric charge. A plasma 15 is at the same potential, and a plasma current 15a as a conduction current flows in accordance with the upper sheath current 12a. This generates an electric field in a lower electrode sheath 13 on the opposite side to the electrode. As a consequence, a lower sheath current 13a indicating the sum of a displacement current, ion current, and electronic current flows in accordance with this electric field. This current and voltage cause a lower electrode plasma side current 13b to flow on the surface of the lower electrode 5. This current further flows out as a lower electrode outside current 5a and a guide rod current 9a. According to the current conservation law, the current value of the upper sheath current 12a is equal to that of the lower sheath current 13a. This constant current value is maintained even in an asymmetric electric field in which, for example, one of the electrodes is grounded. Therefore, it does not matter whether a resonant circuit is provided on the upper electrode side or the lower electrode side, as long as the upper and lower electrodes are included in the resonant circuit.

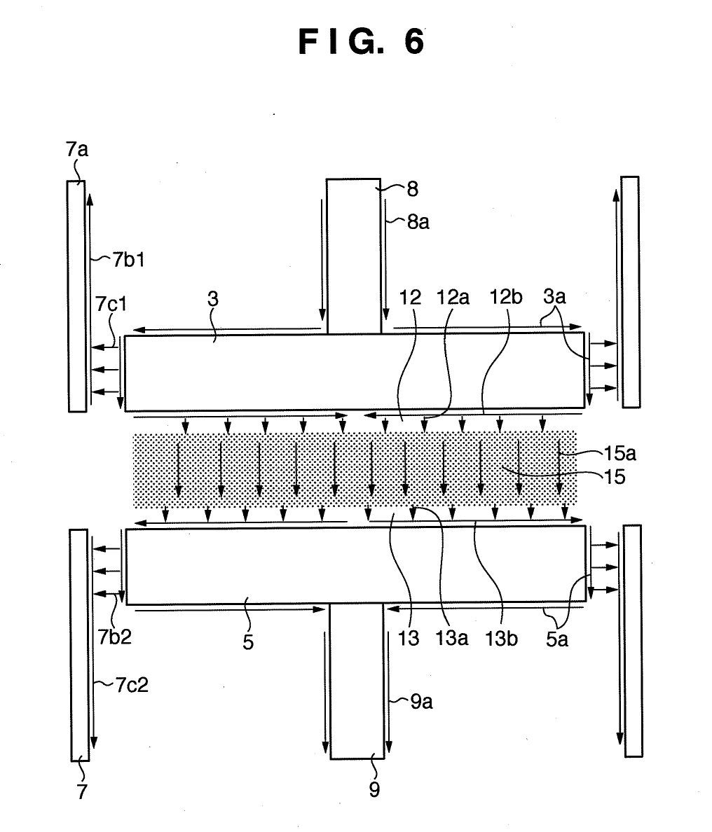

Actual currents, however, do not flow in the above manner. As shown in FIG. 6, some of the currents escape to portions other than the electrodes. That is, some of the upper electrode outside currents 3a escape as currents 7c1 and 7b1 from an upper electrode shield 7a serving as an outer conductor to ground. The value of the upper electrode outside current 3a is larger than that of the lower electrode outside current 5a. In the lower electrode as well, some of the lower electrode outside currents 5.a escape to the lower electrode shield 7, and hence the guide rod current 9a flowing on the surface of the lower electrode guide rod 9 further decreases. In a resonant state, however, since the impedance of the resonant line approaches zero, the amount of current escaping to this parasitic capacitance decreases.

A current escaping to the parasitic capacitance, that is, apparent power, decreases the magnitude of a current or voltage applied to the electrode. For this reason, in order to reduce the parasitic capacitances in the upper electrode shield 7a and the lower electrode shield 7, it is preferable to increase the gaps between the electrodes and shields and decrease the opposing areas so as to reduce the capacitances.

When a resonant state is implemented, the impedances of the electrodes decrease, and power is reflected by the resonance end portion. On the other hand, since currents flow into the resonance portion via the matching circuits without being reflected, the currents stay in the resonance portion, and power is efficiently consumed by the plasma between the upper and lower electrodes in the resonance portion.

The states of the maximum current mode and maximum voltage mode will be described next.

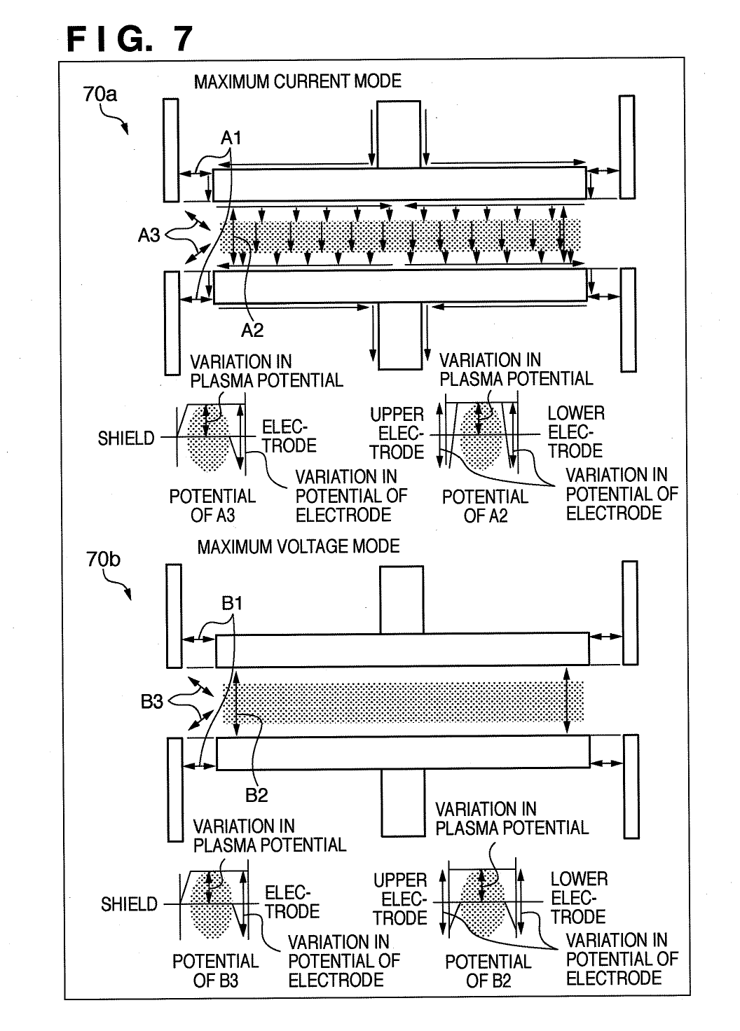

Reference numeral 70a in FIG. 7 denotes the maximum current mode. In the maximum current mode, potential differences A1 between the electrodes and the shields and potential differences A3 between a thin plasma near the shields and the electrodes should be almost negligible values. In addition, if no current stays, a voltage A2 between the electrodes should be low. In practice, however, not much current flows between the plasma and the upper electrode and between the plasma and the lower electrode, and most of the currents become displacement currents. As a consequence, electric charge is accumulated on the surface of electrodes and plasma, resulting in a large voltage.

On the other hand, almost no displacement current flows in the plasma, and a large conduction current flows, resulting in efficient ionization. Although some of the currents flow as real currents into the plasma, since the remaining currents flow from the outer circumference of each electrode to the inner circumference, a potential difference is generated between a peripheral portion of the electrode and the center of the electrode in accordance with a phase difference corresponding to the electrode length. If the center of the electrode coincides with the maximum current/minimum voltage, the difference between the electrode potential and the plasma potential increases toward the outer circumference, and a higher plasma generation density can be obtained at the outer circumference of the electrode than at the center of the electrode. This compensates for the loss of plasma due to dispersion. For this reason, a more uniform plasma density can be easily obtained. However, the plasma density increases at a central portion due to the phenomenon that currents transmitted as waves concentrate on the center of the electrode. If a uniform plasma cannot be obtained as described above, it suffices to increase the ratio of voltage, as will be described later.

Consider that as the potential differences A2 between the electrodes increase, the potential differences A1 between the shields and the electrodes and the potential differences A3 between the shields and the plasma near the shields change, and also consider accompanying influences.

When the center of each electrode coincides with a phase position corresponding to zero voltage, the voltages at the upper and lower electrodes have the same absolute value and opposite signs. The plasma potential does not become lower than the potential at each electrode and varies between half of the potential difference between the electrodes, that is, zero potential, and the peak potential. At this time, no plasma is generated by the electrode at the same potential as the plasma, but a large amount of plasma is generated by the electrode at the opposite potential to that of the plasma because a potential equal to the peak-to-peak potential is generated.

On the other hand, the potential difference between the outer circumference plasma and each electrode is eliminated by the sheath of the electrode portion, and hence does not contribute to the generation of the outer circumference plasma. As the potential difference between the upper electrode 3 and the lower electrode 5 increases, the potential differences between the upper and lower electrodes and the shields 7 and 7a forming the outer conductors increase. However, since there are insulators between the shields and the electrodes, even an increase in potential differences A1 between the shields and the electrodes does not allow plasma generation.

A problem arises in terms of the potential difference A3 between each shield and an outer circumference plasma which varies with a magnitude half of the potential difference between the electrodes. If the shield is fully grounded, the potential of the shield is zero. As considered above, the potential of an outer circumference plasma varies with a value half of the peak-to-peak potential, and the potential difference between the shield and the outer circumference plasma becomes half of the potential difference between the electrode and the plasma. As a consequence, plasma is generated even though the amount of plasma is smaller than that at the electrode portion. If the plasma is sufficiently attenuated and eliminated at the shield portion, such potential difference is not generated. However, the plasma at the outer circumferential portion cannot be sufficiently attenuated by the technique of this embodiment alone, and hence the generation of plasma cannot be suppressed. Therefore, another technique is required.

Reference numeral 70b in FIG. 7 denotes the maximum voltage mode. In this case, the electrode voltage greatly fluctuates. This voltage is applied to voltages B1 and B3 between the electrodes and the shields to generate plasma between the shields and the outer circumference plasma which varies with a value half of the peak-to-peak potential. In contrast to this, the voltage indicated by B2 should be almost zero. In practice, however, the potential of plasma cannot be increased beyond the potential of a portion in which the plasma is in contact, and hence a potential difference half the peak-to-peak potential is applied between the plasma and the electrode. In practice, since a current and voltage 180° out of phase from the inner conductor (electrode) flow in the outer conductor (shield), this consideration is insufficient. However, the above consideration qualitatively holds.

Sufficiently separating the inner conductor (electrode) from the outer conductor (shield) reduces the influence of an increase in voltage at the inner conductor in the maximum current mode on the outer conductor. A problem is that the voltage generated between the electrodes in the maximum current mode generates a current corresponding to the voltage. This can be considered as follows. When an inductor with an impedance having the same absolute value and an opposite sign as the electrode is connected near the electrode, the voltage generated by the inductor cancels the voltage generated by the electrode. Although this arrangement is preferable, the electrical length adjusting unit 70 in FIG. 2 has the same function and can cancel the voltage generated by the electrode to prevent the voltage from influencing other components without using the inductor.

The above can be summarized as follows. In the maximum current mode, plasma at each electrode is generated by the peak-to-peak potential, and a plasma at a peripheral portion is generated by half the peak-to-peak potential. In contrast, in the maximum voltage mode, plasmas are generated on the basis of half the peak-to-peak potential at both the electrode portion and the peripheral portion. Increasing the ratio of voltage in this manner will increase the plasma density at the outer circumferential portion and decrease the plasma density at the central portion as compared with the maximum current mode. The uniformity of plasma density can be changed by changing the current/voltage ratio in a resonant state, that is, the position of each electrode on the resonant circuit.

If no distribution can be obtained in the maximum current mode, the current/voltage ratio is set to about 3/1 by shifting each electrode from a phase position in the maximum current mode which is regarded as a short-circuited end by ± 1/20 wavelength. This improves the in-plane distribution in the first etching process from ±15% to ±4%.

When the lower electrode 5 is to be grounded with respect to the power supply frequency of the upper electrode 3, that is, the lower electrode 5 serves as an outer conductor, the upper electrode 3 needs to be set in the maximum voltage mode in contrast to the above description. In this case, however, since the upper electrode is an open end in a resonant state, the maximum voltage can be achieved automatically. In practice, the lower electrode 5 does not perfectly become an outer conductor and more or less includes a capacitor element. For this reason, there is room to adjust the electrode at the maximum voltage. This can be implemented according to the above description, but a detailed description will be omitted.

If no distribution is obtained in the maximum voltage mode, the current/voltage ratio is set to about ⅓ by shifting each electrode from a phase position in the maximum voltage mode which is regarded as a short-circuited end by ± 1/20 wavelength. This improves the in-plane distribution in the first etching process from ±10% to ±4%.

As has been described above, in this embodiment, a variable capacitor or a variable inductor is provided to adjust a phase position. However, it suffices to achieve resonance by setting the electrical circuit length of the apparatus by calculation or experiment so as to optimize the phase position of each electrode. In this case, referring to, for example, FIG. 1, there is no need to use the electrical length adjusting units 50 and 70 which cause resonance, and it is possible to omit the capacitors and inductors in the corresponding portions or use fixed capacitors and inductors. In addition, in order to place the electrodes at desired resonant phase positions, the lengths of the electrode rods can be designed to desired values.

For the sake of simplicity, it was assumed that resonance occurred between each matching circuit and ground. It is however, more preferable to consider resonance in consideration of the circuit length of the total route extending from the matching circuit to the matching circuit through the electrodes and the electrical length adjusting units.

As described above, according to this embodiment, it is possible to determine which phase position in resonance each electrode occupies in a resonant state and to increase, for example, the current value or the voltage value. In addition, since a phase position can be selected, the reproducibility of a plasma process can be improved. In addition, a plasma state such as a high plasma density can be determined.

As described above, according to this embodiment, there can be provided a user-friendly, highly reliable plasma surface treatment apparatus which can accurately control a plasma state.

Obviously, the above technique can be used to start or maintain electric discharge with a low gas pressure. Since the voltage between the electrodes increases, electric discharge can be easily started even at a low atmospheric pressure at which electric discharge does not easily start. This has the effect of reducing the amount of obliquely incident ions in, for example, an etching process and obtaining a desired etched shape without any bowing even when forming a contact hole having a high aspect ratio. In addition, since the plasma density increases, a contact hole having a high aspect ratio or the like can be quickly etched at a high selectivity.

This embodiment has been described by exemplifying the plasma apparatus in general. Obviously, however, this embodiment can be applied to an etching apparatus using a plasma, sputtering, plasma CVD, ashing, surface oxidation, nitriding, a surface reforming apparatus which removes a compound such as an oxide on a surface, and the like.

The preferred embodiment of the present invention has been described above with reference to the accompanying drawings. However, the present invention is not limited to the embodiment and various changes and modifications can be made within the technical scope defined by the appended claims.

The present invention is not limited to the above embodiment, and can be variously changed and modified without departing from the spirit and scope of the invention. Therefore, to apprise the public of the scope of the present invention, the following claims are made.

This application claims the benefit of Japanese Patent Application No. 2007-176287, filed Jul. 4, 2007, which is hereby incorporated by reference herein in its entirety.

1. A surface treatment apparatus comprising:
a vacuum chamber in which a substrate to be processed is accommodated said vacuum chamber being configured to be evacuated
an upper electrode and a lower electrode, which are arranged in said vacuum chamber so as to face each other;
first RF power supply means for supplying first RF power to said upper electrode via a first matching circuit;
second RF power supply means for supplying second RF power to said lower electrode via a second matching circuit;
a resonant circuit, which is connected between said lower electrode and ground; and
process gas supply means for supplying a process gas into said vacuum chamber, wherein said process gas supply means performs a treatment on a surface of said substrate by generating a plasma of said process gas between said upper electrode and said lower electrode;
electrode phase position adjusting means for adjusting phase positions of said electrodes, wherein said electrode phase position adjusting means includes a variable capacitor or a variable inductor, and said electrode phase position adjusting means is connected at least in a part between said upper electrode and said first matching circuit and in a part between said lower electrode and said resonant circuit.

2. (canceled)

3. The surface treatment apparatus according to claim 1, wherein said electrode phase position adjusting means adjusts said phase positions of said electrodes such that said electrodes are placed at phase positions at which a voltage is maximized and a current is minimized by said electrodes or phase positions at which a voltage is minimized and a current is maximized by said electrodes.

4. A surface treatment apparatus comprising:
a vacuum chamber in which a substrate to be processed is accommodated, said vacuum chamber being configured to be evacuated;
an upper electrode and a lower electrode, which are arranged in said vacuum chamber so as to face each other;
first RF power supply means for supplying first RF power to said upper electrode via a first matching circuit;
second RF power supply means for supplying second RF power to said lower electrode via a second matching circuit;
a resonant circuit which is connected between said lower electrode and ground; and
process gas supply means for supplying a process gas into said vacuum chamber, wherein said process gas supply means performs a treatment on a surface of said substrate by generating a plasma of said process gas between said upper electrode and said lower electrode,
wherein said upper electrode is placed at a position shifted from a phase position regarded as a short-circuited end by ± 1/20 wavelength of said second RF power.

5. The surface treatment apparatus according to claim 1, wherein said resonant circuit includes a voltage measuring instrument and a current measuring instrument.

6. The surface treatment apparatus according to claim 4, wherein said resonant circuit includes a voltage measuring instrument and a current measuring instrument.
